(19) United States
(12) Patent Application Publication
(10) Pub. No.: US 2003/0124834 A1
(43) Pub. Date: Jul. 3, 2003

(54) Method and system of wire bonding for use in fabrication of semiconductor package

(75) Inventors: David Tseng, Feng Yuan (TW); Chien-Ping Huang, Hsinchu (TW); Kun-Ming Huang, Chang Hua (TW)

Correspondence Address: EDWARDS & ANGELL, LLP, P.O. BOX 9169, BOSTON, MA, 02209, US

(73) Assignee: Siliconware Precision Industries Co., Ltd.,

(21) Appl. No.: 10/075,043

(22) Filed: Feb. 12, 2002

(30) Foreign Application Priority Data
Dec. 31, 2001 (TW) TW 90133149

(51) Int. Cl. H01L 21/44; H01L 21/48; H01L 21/50

(52) U.S. Cl. 438/617; 438/107

(57) ABSTRACT

A method and a system of wire bonding for use in semiconductor package fabrication are proposed. When one wire-bonded substrate unit of a substrate mounted with chips is introduced into a testing region, a next adjacent substrate unit is simultaneously formed with bonding wires in a wire-bonding region. In the testing region, the wire-bonded substrate unit is tested for wire bonding quality. If no wire opening or short occurs, the wire-bonded substrate unit is readily used for subsequent package fabrication. If wire opening or short is detected, a controlling module associated with the testing region generates a control signal to the wire-bonding region for interrupting a wire-bonding process, whereby causes of wire opening or short are overcome, and defective bonding wires are reworked. Therefore, inferiors or malfunction is timely detected, making overall fabrication process more time-effectively implemented; and inferiors are reworked for later usage, thereby significantly reducing fabrication costs.

### FIELD OF THE INVENTION

The present invention relates to methods and systems of wire bonding, and more particularly, to a method and a system of wire bonding for forming bonding wires that interconnect a chip and a chip carrier accommodating the chip, so as to allow the chip to be electrically connected to the chip carrier.

### BACKGROUND OF THE INVENTION

Generally, BGA (ball grid array) semiconductor packages are fabricated by a series of steps illustrated in FIG. 5. In step 50, pre-dimensioned chips are respectively bonded to predetermined positions on matrix-arrayed or single array-arranged chip carriers by means of adhesives such as silver paste or polyimide tape, Then, in step 51, the chip carriers bonded with the chips are introduced through a handler into a wire bonding machine, where a wire bonding process is performed and a plurality of gold wires are formed to electrically connect the chips to the chip carriers. In step 52, the wire bonded chip carriers and chips are moved out of the wire bonding machine by the handler, and subjected to a next molding process for forming encapsulants that encapsulate the chips and the gold wires on the chip carriers. Subsequently, in step 53, the chip carriers with the encapsulated chips and gold wires are placed into a ball implantation machine, allowing a plurality of array-arranged solder balls to be implanted on surfaces of the chip carriers where no chips are mounted thereon. After solder ball implantation is completed, in step 54, a singulation process is performed, in which a cutting machine is used to cut apart the above integrally-formed chip carriers into individual semiconductor packages. Then, prior to product delivery, in step 55, these singulated semiconductor packages undergo an open/short (O/S) test for examining quality of chip electrical connection. Finally, in step 56, the semiconductor packages passing the quality test are ready to be delivered and shipped.

In the above step 55, the O/S test is used to test if the gold wires for electrically interconnecting the chips and the chip carriers are opened or short-circuited. If wire opening or short circuit occurs, the fabrication process is traced to find out malfunctioning stations, e.g. a wire bonding station, whereby a wire bonding machine is checked and properly adjusted or repaired. However, as inferior products that fail the O/S test are completely fabricated packages, no chance for rework or repair is available rather than discarding the inferior packages. It is therefore impossible to instantly detect failures during package fabrication e.g. in the wire bonding process, making fabrication costs and material waste undesirably increased. Further, if an impaired wire bonding machine cannot be immediately monitored and stopped operating, defective products are continuously fabricated, which leads to more waste in materials and costs.

A high-integration semiconductor package may suffer more severe effects of wire opening or short circuit during wire bonding. A substrate used in such a semiconductor package is usually formed with a ground ring, a power ring and signal fingers thereon, so as to provide sufficient I/O connections for a highly integrated chip accommodated in the semiconductor package. In response to increased I/O connections, more gold wires for electrically connecting the chip to the substrate are formed on restricted surface area of the substrate normally in a manner that, function-different gold wires are arranged at variable heights of wire loops, which can achieve high density of gold wires (500 to 1000 wires) bonded on the substrate; this accordingly reduces pitches between adjacent gold wires from conventionally 80 μm to only about 50 μm, i.e. fine pitches. The highly dense arrangement of gold wires makes neighboring wires easily come into contact with each other and short-circuited. Therefore, how to effectively reduce the occurrence of wire opening or short circuit, and promptly find out an improperly-operating wire bonding machine during fabrication, is a critical problem to solve.

In accordance with the foregoing problem, another package fabrication method is disclosed. As shown in FIG. 6, same as previously illustrated in FIG. 5, this conventional fabrication method is firstly to mount chips on chip carriers in step 60, and then perform a wire bonding process to form gold wires that electrically connect the chips to the chip carriers, in step 61. Thereafter, differently from the method of FIG. 5, in step 62, the wire-bonded chip carriers with the chips are introduced to an O/S test machine for examining if wire opening or short circuit occurs at the gold wires. Those tested semi-fabricated products, if passing the O/S test, are moved out of the O/S test machine and readily subjected to subsequent processes, such as molding (step 63), ball implantation (step 64), singulation (step 65), final O/S test (step 66) and product delivery (step 67). This therefore timely finds out test-failed semi-fabricated products prior to molding and ball-implantation, allowing the inferiors to be possibly reworked or repaired, thereby making fabrication costs and material waste significantly reduced.

However, since the above O/S test machine is actually separate from a test station of normal fabrication process, thus costs, process complexity and cycle time in fabrication are all increased. Moreover, it is rather time-ineffective to firstly move wire-bonded structures out of the wire bonding machine and then transfer them to the O/S test machine for test performance; such a waste of time in transferring degrades time efficiency of the overall fabrication process. In addition, when a certain batch of substrates are found to fail the O/S test, a next batch of substrates simultaneously undergo the wire bonding process; in other words, inferiors or operational malfunction cannot be timely discovered before wire-bonding the next batch of substrates, thereby making it more difficult to retrieve the true causes of wire opening or short circuit, and leading to increase in fabrication costs.

### SUMMARY OF THE INVENTION

A primary objective of the present invention is to provide a method and a system of wire bonding for use in fabrication of a semiconductor package, in which an O/S test is performed during a wire bonding process, making the overall fabrication time effectively shortened.

Another objective of the invention is to provide a method and a system of wire bonding for use in fabrication of a semiconductor package, whereby malfunction of wire bonding machine can be instantly detected, allowing the impaired wire bonding machine to be promptly adjusted and repaired.

Still another objective of the invention is to provide a method and a system of wire bonding for use in fabrication of a semiconductor package, which can reduce fabrication costs and improve product yield.

A further objective of the invention is to provide a method and a system of wire bonding for use in fabrication of a semiconductor package, whereby causes of wire opening or short circuit can be timely traced out during fabrication.

In accordance with the above and other objectives, the present invention proposes a method and a system of wire bonding for use in fabrication of a semiconductor package. The wire bonding method comprises the steps of: (1) preparing a substrate composed of a plurality of substrate units, and mounting at least a chip on each of the substrate units; (2) providing a wire bonding station at least having a wire bonding mechanism and a testing mechanism, so as to allow the substrate mounted with the chips to be introduced into the wire bonding mechanism; (3) forming a plurality of bonding wires on one substrate unit of the substrate via the wire bonding mechanism, so as to electrically connect a corresponding chip to the substrate unit; (4) introducing the wire-bonded substrate unit into the testing mechanism for performing an O/S (open/short) test, and forming bonding wires on a next adjacent substrate of the substrate simultaneously moved into the wire bonding mechanism; wherein if test results indicate no occurrence of wire opening or short circuit for the bonding wires formed on the wire-bonded substrate unit, then step (5) proceeds; wherein if the test results indicate occurrence of wire opening or short circuit for the bonding wires on the wire-bonded substrate unit, the testing mechanism is prompted to generate a control signal to the wire bonding mechanism for interrupting a wire bonding process, whereby the wire bonding mechanism is adjusted or repaired, or other causes of wire opening or short circuit are traced and overcome, so as to rework the bonding wires on the wire-bonded substrate unit, and then repeat the step (4); (5) repeating the step (3) until all the substrate units of the substrate are wire-bonded and tested with the O/S test, and then proceeding with step (6); and (6) moving the wire-bonded and tested substrate out of the wire bonding station, for allowing the substrate to be used in subsequent package fabrication.

The wire bonding station includes a handling mechanism for moving a substrate into or out of the wire bonding station, a wire bonding mechanism for forming bonding wires, and a testing mechanism for performing an O/S test.

The testing mechanism is composed of a test socket internally installed in the wire bonding station, and a tester electrically connected to the test socket. The tester can be provided inside the wire bonding station, or outside the wire bonding station for being electrically connected to test sockets of other wire bonding stations, so as to simultaneously control the plurality of test sockets for performing the O/S test. In addition, the tester is electrically associated with the wire bonding mechanism; when wire opening or short circuit is detected, a controlling module internally installed in the tester generates a control signal to the wire bonding mechanism for interrupting a wire bonding process.

Another embodiment of the wire bonding method for use in fabrication of a semiconductor package of the invention, comprises the steps of: (1) preparing a substrate composed of a plurality of substrate units, and mounting at least a chip on each of the substrate units; (2) providing a wire bonding station at least having a wire bonding mechanism and a testing mechanism, so as to allow the substrate mounted with the chips to be introduced into the wire bonding mechanism; (3) forming a plurality of bonding wires on one substrate unit of the substrate via the wire bonding mechanism, so as to electrically connect a corresponding chip to the substrate unit; (4) introducing the wire-bonded substrate unit into the testing mechanism for performing an O/S test, allowing test results to be displayed by the testing mechanism; and forming bonding wires on a next adjacent substrate of the substrate simultaneously moved into the wire bonding mechanism; (5) repeating the step (4) until all the substrate units of the substrate are wire-bonded and tested with the O/S test, and then proceeding with step (6); (6) moving the wire-bonded and tested substrate out of the wire bonding station; and (7) reworking wire-opened or short-circuited substrate units, and overcoming causes of wire opening or short circuit according to the displayed test results by the testing mechanism.

The testing mechanism includes a test socket and a tester electrically connected to the test socket. The tester at least has a testing module for testing if wire opening or short circuit occurs for bonding wires formed on a substrate, and a displaying module for displaying test results from the test module. According to the test results displayed by the displaying module, an operator can examine the bonding quality of each bonding wire on the substrate, and timely repair or rework defective bonding wires with the occurrence of wire opening or short circuit.

A further embodiment of the wire bonding method for use in fabrication of a semiconductor package of the invention, comprises the steps of: (1) preparing a substrate composed of a plurality of substrate units, and mounting at least a chip on each of the substrate units; (2) providing a wire bonding station at least having a wire bonding mechanism and a testing mechanism, so as to allow the substrate mounted with the chips to be introduced into the wire bonding mechanism; (3) forming a plurality of bonding wires on one substrate unit of the substrate via the wire bonding mechanism, so as to electrically connect a corresponding chip to the substrate unit; (4) introducing the wire-bonded substrate unit into the testing mechanism for performing an O/S test, and forming bonding wires on a next adjacent substrate of the substrate simultaneously moved into the wire bonding mechanism; (5) proceeding with step (7) if test results indicate no occurrence of wire opening or short circuit for the bonding wires formed on the wire-bonded substrate unit; wherein, if no wire opening or short circuit occurs; or else, a controlling module of the testing mechanism determining if a pre-inputted command to the testing mechanism is to interrupt a wire bonding process in the wire bonding mechanism; wherein, if the pre-inputted command is interruption of the wire bonding process, then step (6) proceeds; or else, step (9) proceeds; (6) generating a control signal via the controlling module of the testing mechanism to the wire bonding mechanism for interrupting the wire bonding process, so as to trace and overcome causes of wire opening or short circuit, and to rework the wire-bonded substrate unit; then repeating the step (4); (7) repeating the step (3) until all the substrate units of the substrate are wire-bonded and tested with the O/S test, and then proceeding with step (8); (8) moving the wire-bonded and tested substrate out of the wire bonding station, for allowing the substrate to be used in subsequent package fabrication; (9) displaying test results produced from the step (5) via a displaying module of the testing mechanism, and repeating the step (3) until all the substrate units of the substrate are wire-bonded and tested with the O/S test; then proceeding with step (10); (10) moving the wire-bonded and tested substrate out of the wire bonding station; and (11) reworking wire-opened or short-circuited substrate units, and tracing and overcoming causes of wire opening or short circuit according to the displayed test results by the displaying module of the testing mechanism.

A wire bonding system for use in fabrication of a semiconductor package of the invention, comprises: a handling mechanism for moving a substrate into or out of the wire bonding system, the substrate being composed of a plurality of substrate units, with each of the substrate units being mounted with at least a chip; a wire bonding mechanism for forming bonding wires on the substrate introduced by the handling mechanism, allowing each of the chips to be electrically connected to the corresponding substrate unit by the bonding wires; and a test mechanism having a test socket and a tester electrically connected to the test socket, for testing if wire opening or short circuit occurs for each of the wire-bonded substrate units of the substrate, wherein, when wire opening or short circuit is detected, the tester generates a control signal to the wire bonding mechanism, whereby the wire bonding mechanism interrupts a wire bonding process, and makes proper adjustment and repair for overcoming the causes of wire opening or short circuit.

### BRIEF DESCRIPTION OF THE DRAWINGS

The present invention can be more fully understood by reading the following detailed description of the preferred embodiments, with reference made to the accompanying drawings, wherein:

FIG. 1 is a schematic diagram showing the operation of a wire bonding system of a first preferred embodiment of the invention;

FIG. 2 is a flowchart showing the steps involved in a wire bonding method of a first preferred embodiment of the invention;

FIG. 3 is a flowchart showing the steps involved in a wire bonding method of a second preferred embodiment of the invention;

FIG. 4 is a flowchart showing the steps involved in a wire bonding method of a third preferred embodiment of the invention;

FIG. 5 (PRIOR ART) is a flowchart showing the steps involved in fabrication of a conventional semiconductor package; and

FIG. 6 (PRIOR ART) is a flowchart showing the steps involved in fabrication of another conventional semiconductor package.

### DETAILED DESCRIPTION OF THE PREFERRED EMBODIMENT

First Preferred Embodiment

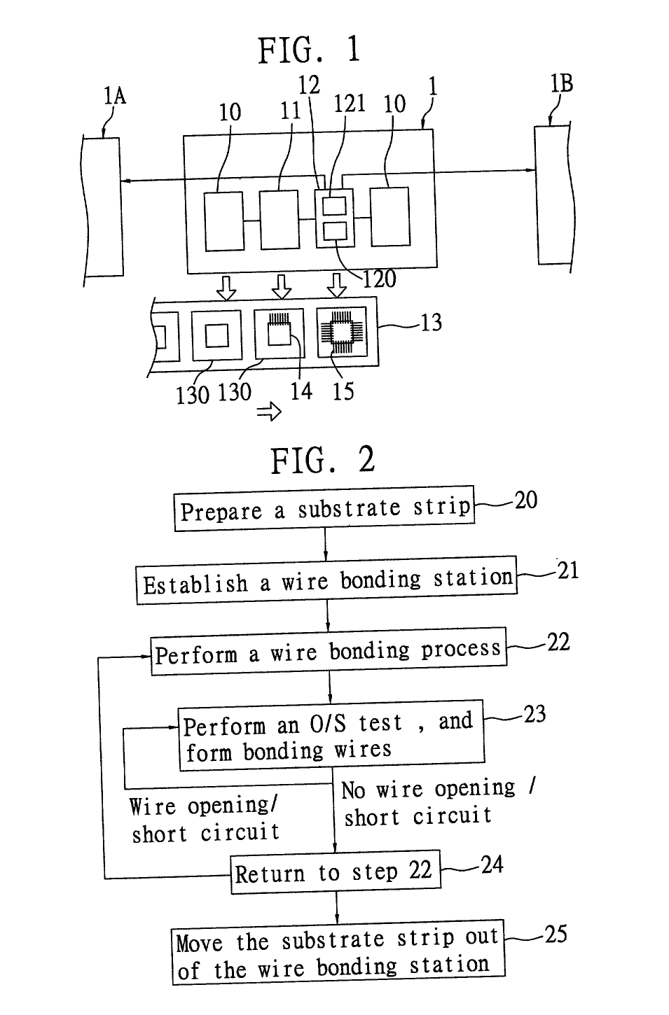

FIG. 1 illustrates the operation of a wire bonding system of the first embodiment of the present invention.

As shown in the drawing, the wire bonding system 1 comprises: a handler 10, a wire bonding mechanism 11 and an O/S (open/short) testing mechanism 12.

The handler 10 and the wire bonding mechanism 11 are identical to those for a conventional wire bonding machine, and not to be farther described herein. The O/S testing mechanism 12 includes at least a test socket 120 and a tester 121 electrically connected to the test socket 120. The test socket 120 is disposed at a downstream position relative to the wire bonding mechanism 11, and comes into contact with a test subject that is introduced by the handler 10 and wire-bonded in the wire bonding mechanism 11, so as to allow the tester 121 to test if wire opening or short circuit occurs in the test subject. The tester 121 can further be connected to respective test sockets (not shown) of other wire bonding systems 1A, 1B shown in FIG. 1. In other words, the tester 121 can be electrically coupled to test sockets used in a plurality of wire bonding systems based on the functional design of the tester 121, and simultaneously examine the electrical connection of multiple test subjects in contact with those test sockets. Moreover, besides a conventional testing module (not shown), the tester 121 is also provided with at least a controlling module (not shown) associated with the testing module, whereby test results from the testing module can be received and determined by the controlling module. When the test subject is found to be wire-opened or short-circuited, the controlling module electrically connected to the wire bonding mechanism 11, would generate a control signal to the wire bonding mechanism 11 for stopping the proceeding of wire bonding.

Referring to FIG. 2, a wire bonding method of the first embodiment of the invention comprises the steps as follows.

First in step 20, referring to FIG. 1, a substrate strip 13 composed of a plurality of substrate units 130 is prepared, and a chip 14 is mounted on each of the substrate units 130. Since the substrate preparation and die bonding process are conventional technology, no further description thereof is to be repeated herein. It is understood that, the substrate units 130 of the substrate strip 13 can be arranged in a matrix type or single-column type, but not particularly limited; the single-column type arrangement is illustrated in FIG. 1.

In step 21, a wire bonding station 1 is provided, and comprises a handler 10, a wire bonding mechanism 11 and an O/S testing mechanism 12, as shown in FIG. 1.

In step 22, the handler 10 introduces the substrate strip 13 mounted with the chips 14 into the wire bonding mechanism 11, so as to form a plurality of bonding wires 15 on one substrate unit 130 of the substrate strip 13, allowing a corresponding chip 14 to be electrically connected to this substrate unit 130 by the bonding wires 15.

In step 23, after completing the wire bonding step 22, the substrate unit 130 bonded with the bonding wires 15 are moved to the O/S testing mechanism 12, in which an O/S test is performed for the bonding wires 15. At the same time, the handler 10 is prompted to again move the substrate strip 13, and introduce a next adjacent substrate unit 130 into the wire bonding mechanism 11 to form bonding wires 15. In proceeding of the O/S test, a test socket 120 of the O/S testing mechanism 12 is firstly made to be into contact with a predetermined position on the substrate unit 130, and then a testing module of a tester 121 in the O/S testing mechanism 12 performs the O/S test. If the substrate unit 130 passes the test with no occurrence of wire opening or short circuit, then step 24 is carried out. On the other hand, if the substrate unit 130 is tested to be wire-opened or short-circuited, a controlling module of the tester 121 receives a test-failure signal from the testing module, and responsively generates a control signal to the wire bonding mechanism 11 that is electrically associated with the controlling module, whereby the wire bonding mechanism 11 stops proceeding with the wire bonding process after the next adjacent substrate unit 130 is completely wire-bonded. An operator adjusts or repairs the wire bonding mechanism 11, or traces and overcomes the causes of wire opening or short circuit, e.g. inferior material quality of bonding wires or substrate. The defective wire-bonded substrate unit 130 is reworked and undergoes the O/S test of the step 23 repeatedly until no further occurrence of wire opening or short circuit is detected; at this time, step 24 can be readily executed.

In step 24, the step 22 is repeated until all the substrate units 130 of the substrate strip 13 are wire-bonded with bonding wires 15 and tested with the O/S test. Thereafter, step 25 proceeds.

Finally, in step 25, the wire-bonded and tested substrate strip 13 is moved by the handler 10 out of the wire bonding station 1, and subsequently subjected to molding, ball implantation and singulation processes; this completes the fabrication of semiconductor packages.

In the wire bonding method of the invention, since an O/S test is performed in a wire bonding station or in an O/S testing mechanism integrally formed with a wire bonding machine, thus the occurrence of wire opening or short circuit is timely detected, and causes thereof is promptly traced and overcome. This can desirably prevent batch production of inferiors, and reduce fabrication costs.

Furthermore, generally it takes three to six minutes for completing the bonding of 500 to 1000 bonding wires on a substrate unit, but testing the wire-bonded substrate unit only needs three to five seconds. Therefore, the wire bonding method of the invention characterized in the simultaneous proceeding of the O/S test and wire bonding process, is advantageous of including the test-performing time in the conventional fabrication schedule. That is, the wire bonding method of the invention is time-effective to implement and significantly shortens the overall fabrication time, as well as helps reduce fabrication costs without increasing process complexity.

Furthermore, for the second conventional fabrication method as previously described, an O/S tester used therein is separately purchased, and mainly composed of a handler and a testing mechanism, wherein the handler costs around 70% of the total machine price, thereby making the price of this conventional tester hardly drop. On the contrary, in the wire bonding method of the invention, the testing mechanism is integrated into the wire bonding station, and shares a common handler with a wire bonding machine of the wire bonding station, so that equipment and fabrication costs can be greatly reduced.

Second Preferred Embodiment

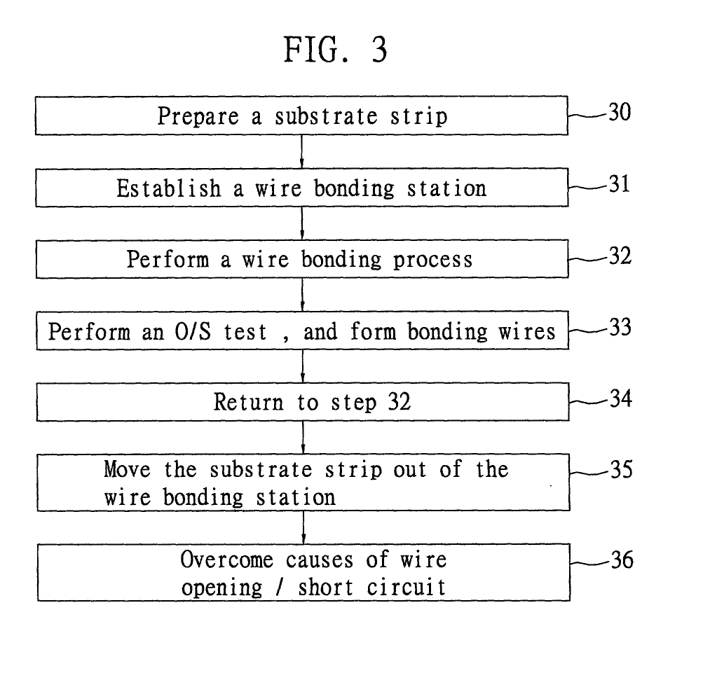

Referring to FIGS. 3 and 1, in a bonding wire method of the second embodiment of the invention, steps 30 to 32 respectively for preparing a substrate strip 13, establishing a wire bonding station 1 and forming bonding wires 15, are same as steps 20 to 22 previously described in the first embodiment, and therefore not to be further detailed herein.

In step 33, after completing the step 32 for forming the bonding wires 15 on a substrate unit 130 of the substrate strip 13 in a wire bonding mechanism 11, the wire-bonded substrate unit 130 is introduced to an O/S testing mechanism 12, where an O/S test is performed for the bonding wires 15. Simultaneously, the substrate strip 13 is again moved by a handler 10, allowing a next adjacent substrate unit 130 to be introduced into the wire bonding mechanism 11 and bonded with bonding wires 15 thereon. Moreover, O/S test results for the bonding wires 15 are displayed in the O/S testing mechanism 12; in particular, a testing module (not shown) of the O/S testing mechanism 12 transmits the test results to a displaying module (not shown) that is electrically connected to the testing module, whereby the test results are displayed by the displaying module and processed by an operator.

In step 34, the step 33 is repeated until all substrate units 130 of the substrate strip 13 are wire-bonded with bonding wires 15 and tested with the O/S test, allowing all O/S test results to be displayed by the displaying module of the O/S testing mechanism 12.

In step 35, the handler 10 moves the wire-bonded and tested substrate strip 13 out of the wire bonding station 1.

Finally, in step 36, according to the displayed test results, the operator finds out wire-opened or short-circuited substrate units 130 of the substrate strip 13, and makes operational adjustment or replacement in order to overcome the causes of wire opening or short circuit. The defective substrate units 130 are reworked, and the reworked substrate strip 13 can then be subjected to molding, ball implantation and singulation processes for package fabrication.

Third Preferred Embodiment

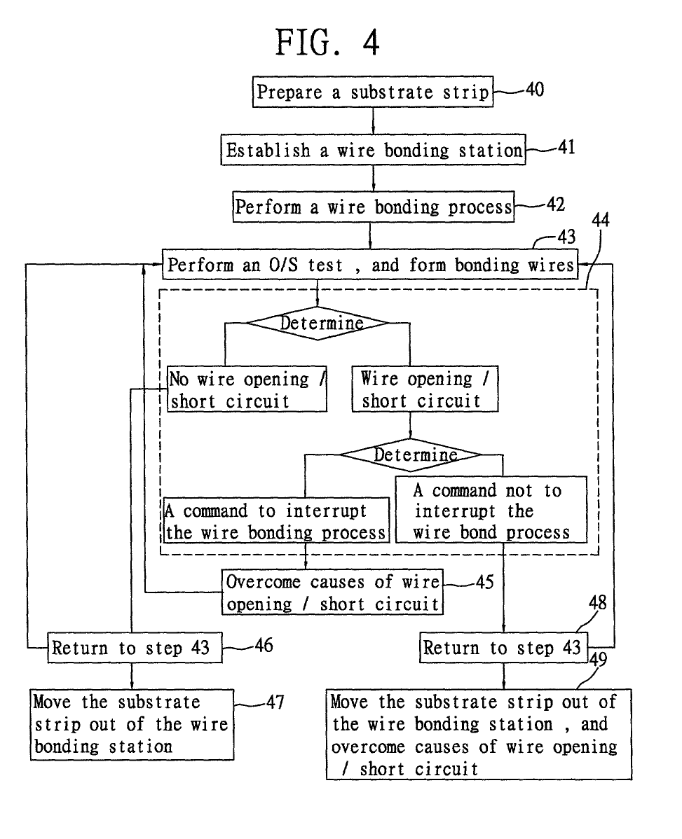

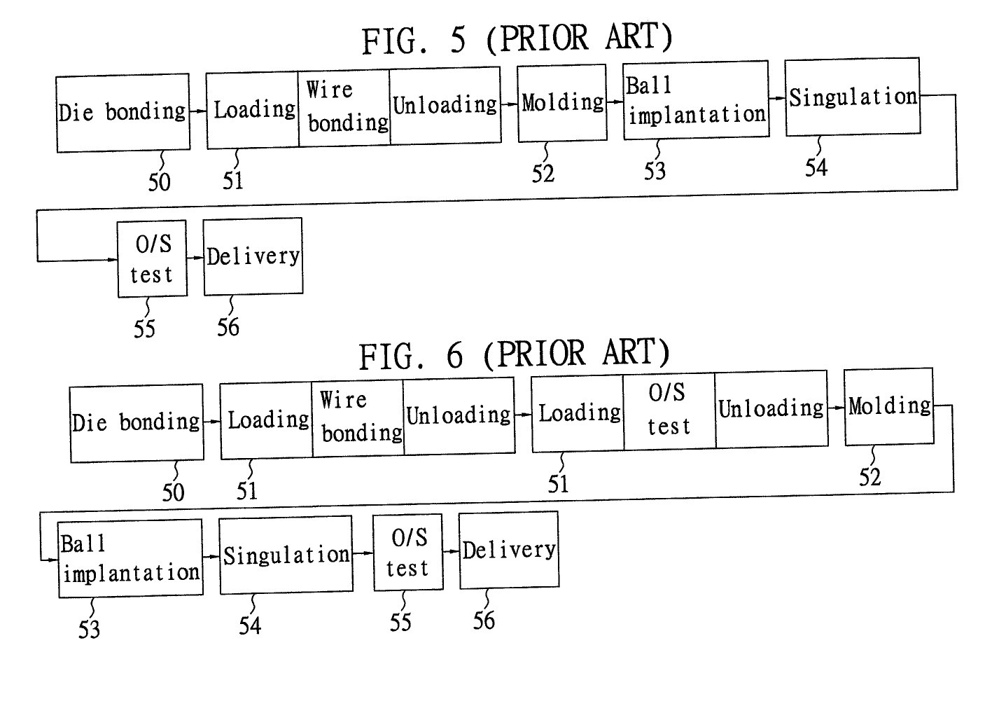

Referring to FIGS. 4 and 1, in a bonding wire method of the third embodiment of the invention, steps 40 to 42 respectively for preparing a substrate strip 13, establishing a wire bonding station 1 and forming bonding wires 15, are same as steps 20 to 22 previously described in the first embodiment, and therefore not to be further detailed herein.

In step 43, after completing the step 42 for forming the bonding wires 15 on a substrate unit 130 of the substrate strip 13 in a wire bonding mechanism 11, the wire-bonded substrate unit 130 is introduced to an O/S testing mechanism 12, where an O/S test is performed for the bonding wires 15. Simultaneously, the substrate strip 13 is again moved by a handler 10, allowing a next adjacent substrate unit 130 to be introduced into the wire bonding mechanism 11 and bonded with bonding wires 15 thereon.

In step 44, if the substrate unit 130 passes the O/S test with no occurrence of wire opening or short circuit for the bonding wires 15, then step 46 is carried out; or otherwise, a controlling module (not shown) of the O/S testing mechanism 12 determines if a pre-inputted command from an operator to the O/S testing mechanism 12 is to stop the wire bonding mechanism 11 proceeding with the wire bonding process. If the pre-inputted command is wire bonding interruption, then step 45 is executed; or else, step 48 is performed.

In step 45, the controlling module of the O/S testing mechanism 12 is prompted to generate a control signal to the wire bonding mechanism 11 that is electrically associated with the controlling module, whereby the wire bonding process is interrupted after the next adjacent substrate unit 130 is completely wire-bonded. This allows the operator to trace and promptly overcome the causes of wire opening or short circuit, and to rework the defective wire-bonded substrate unit 130. Then, the step 43 returns.

In step 46, the step 43 is repeated until all substrate units 130 of the substrate strip 13 are wire-bonded with bonding wires 15 and tested with the O/S test. Thereafter, step 47 proceeds.

In step 47, the handler 10 moves the wire-bonded and test-passed substrate strip 13 in the step 46 out of the wire bonding station 1 for subsequent use in package fabrication.

In step 48, O/S test results from the step 44 are displayed by a displaying module (not shown) of the O/S testing mechanism 12, and the step 43 is repeated until all substrate units 130 of the substrate strip 13 are wire-bonded with bonding wires 15 and tested with the O/S test. Thereafter, step 49 proceeds.

In step 49, first, the wire-bonded substrate strip 13 in the step 48 is moved out of the wire bonding station 1. Then, according to the displayed test results, the operator traces and promptly overcomes the causes of wire opening or short circuit, and reworks defective wire-opened or short-circuited substrate units 130, so as to assure the quality of substrate units 130 for use in subsequent package fabrication.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A wire bonding method for use in fabrication of a semiconductor package, comprising the steps of:
(1) preparing a substrate composed of a plurality of substrate units, and mounting at least a chip on each of the substrate units;
(2) providing a wire bonding station at least having a wire bonding mechanism and a testing mechanism, so as to allow the substrate mounted with the chips to be introduced into the wire bonding mechanism;
(3) forming a plurality of bonding wires on one substrate unit of the substrate via the wire bonding mechanism, so as to electrically connect a corresponding chip to the substrate unit;
(4) introducing the wire-bonded substrate unit into the testing mechanism for performing an O/S (open/short) test, and forming bonding wires on a next adjacent substrate of the substrate simultaneously moved into the wire bonding mechanism; wherein if test results indicate no occurrence of wire opening or short circuit for the bonding wires formed on the wire-bonded substrate unit, then step (5) proceeds; wherein if the test results indicate occurrence of wire opening or short circuit for the bonding wires on the wire-bonded substrate unit, the testing mechanism is prompted to generate a control signal to the wire bonding mechanism for interrupting a wire bonding process, whereby the wire bonding mechanism is adjusted or repaired, or other causes of wire opening or short circuit are traced and overcome, so as to rework the bonding wires on the wire-bonded substrate unit, and then repeat the step (4);
(5) repeating the step (3) until all the substrate units of the substrate are wire-bonded and tested with the O/S test, and then proceeding with step (6); and
(6) moving the wire-bonded and tested substrate out of the wire bonding station, for allowing the substrate to be used in subsequent package fabrication.

2. The wire bonding method of claim 1, wherein the testing mechanism includes at least a test socket and a tester electrically connected to the test socket.

3. The wire bonding method of claim 2, wherein the test socket is used to come into contact with the wire-bonded substrate unit, allowing the tester to perform the O/S test for the bonding wires on the substrate unit through the test socket.

4. The wire bonding method of claim 2, wherein the tester at least includes:
a testing module electrically connected to the test socket, for performing the O/S test through the test socket; and
a controlling module electrically connected to the testing module and the wire bonding mechanism, for receiving a test-failure signal from the testing module in occurrence of wire opening or short circuit, and generating a control signal to the wire bonding mechanism, so as to interrupt the wire bonding process in the wire bonding mechanism.

5. The wire bonding method of claim 2, wherein the tester is further electrically connected to a test socket of at least another wire bonding station, so as to simultaneously control test sockets in a plurality of wire bonding stations for performing the O/S test.

6. The wire bonding method of claim 1, wherein the wire bonding station further includes a handling mechanism for moving the substrate into or out of the wire bonding station.

7. The wire bonding method of claim 1, wherein the wire bonding station is a wire bonding machine internally provided with the testing mechanism, and the testing mechanism is disposed at a downstream position relative to the wire bonding mechanism in the wire bonding machine.

8. The wire bonding method of claim 1, wherein the wire bonding station includes a wire bonding machine internally provided with at least a test socket, and a tester externally connected to the wire bonding machine and electrically connected to the test socket, which test socket is disposed at a downstream position relative to the wire bonding mechanism.

9. The wire bonding method of claim 1, wherein in the step (4), upon receiving the control signal from the testing mechanism, the wire bonding mechanism interrupts the wire bonding process after the next adjacent substrate unit is completely wire-bonded.

10. The wire bonding method of claim 1, wherein the substrate units of the substrate are arranged in a matrix type.

11. The wire bonding method of claim 1, wherein the substrate units of the substrate are arranged in a single-array type.

12. A wire bonding method for use in fabrication of a semiconductor package, comprising the steps of:
(1) preparing a substrate composed of a plurality of substrate units, and mounting at least a chip on each of the substrate units;
(2) providing a wire bonding station at least having a wire bonding mechanism and a testing mechanism, so as to allow the substrate mounted with the chips to be introduced into the wire bonding mechanism;
(3) forming a plurality of bonding wires on one substrate unit of the substrate via the wire bonding mechanism, so as to electrically connect a corresponding chip to the substrate unit;
(4) introducing the wire-bonded substrate unit into the testing mechanism for performing an O/S (open/short) test, and forming bonding wires on a next adjacent substrate of the substrate simultaneously moved into the wire bonding mechanism; then, displaying test results via the testing mechanism;
(5) repeating the step (4) until all the substrate units of the substrate are wire-bonded and tested with the O/S test, and then proceeding with step (6); and
(6) moving the wire-bonded and tested substrate out of the wire bonding station; reworking wire-opened or short-circuited substrate units, and overcoming causes of wire opening or short circuit according to the displayed test results by the testing mechanism in the step (4).

13. The wire bonding method of claim 12, wherein the testing mechanism includes at least a test socket and a tester electrically connected to the test socket.

14. The wire bonding method of claim 13, wherein the test socket is used to come into contact with the wire-bonded substrate unit, allowing the tester to perform the O/S test for the bonding wires on the substrate unit through the test socket.

15. The wire bonding method of claim 13, wherein the tester at least includes:
a testing module electrically connected to the test socket, for performing the O/S test through the test socket; and
a displaying module connected to the testing module, for displaying test results from the testing module.

16. The wire bonding method of claim 13, wherein the tester is further electrically connected to a test socket of at least another wire bonding station, so as to simultaneously control test sockets in a plurality of wire bonding stations for performing the O/S test.

17. The wire bonding method of claim 12, wherein the wire bonding station further includes a handling mechanism for moving the substrate into or out of the wire bonding station.

18. The wire bonding method of claim 12, wherein the wire bonding station is a wire bonding mace, internally provided with the testing mechanism, and the testing mechanism is disposed at a downstream position relative to the wire bonding mechanism in the wire bonding machine.

19. The wire bonding method of claim 12, wherein the wire bonding station includes a wire bonding machine internally provided with at least a test socket, and a tester externally connected to the wire bonding machine and electrically connected to the test socket, which test socket is disposed at a downstream position relative to the wire bonding mechanism.

20. The wire bonding method of claim 12, wherein the substrate units of the substrate are arranged in a matrix type.

21. The wire bonding method of claim 12, wherein the substrate units of the substrate are arranged in a single-array type.

22. A wire bonding method for use in fabrication of a semiconductor package, comprising the steps of:
(1) preparing a substrate composed of a plurality of substrate units, and mounting at least a chip on each of the substrate units;
(2) providing a wire bonding station at least having a wire bonding mechanism and a testing mechanism, so as to allow the substrate mounted with the chips to be introduced into the wire bonding mechanism;
(3) forming a plurality of bonding wires on one substrate unit of the substrate via the wire bonding mechanism, so as to electrically connect a corresponding chip to the substrate unit;
(4) introducing the wire-bonded substrate unit into the testing mechanism for performing an O/S (open/short) test, and forming bonding wires on a next adjacent substrate of the substrate simultaneously moved into the wire bonding mechanism;
(5) proceeding with step (7) if test results indicate no occurrence of wire opening or short circuit for the bonding wires formed on the wire-bonded substrate unit; wherein, if no wire opening or short circuit occurs; or else, a controlling module of the testing mechanism determining if a pre-inputted command to the testing mechanism is to interrupt a wire bonding process in the wire bonding mechanism; wherein, if the pre-inputted command is interruption of the wire bonding process, then step (6) proceeds; or else, step (9) proceeds;
(6) generating a control signal via the controlling module of the testing mechanism to the wire bonding mechanism for interrupting the wire bonding process, so as to trace and overcome causes of wire opening or short circuit, and to rework the wire-bonded substrate unit; then repeating the step (4);
(7) repeating the step (3) until all the substrate units of the substrate are wire-bonded and tested with the O/S test, and then proceeding with step (8);
(8) moving the wire-bonded and tested substrate out of the wire bonding station, for allowing the substrate to be used in subsequent package fabrication;
(9) displaying test results produced from the step (5) via a displaying module of the testing mechanism, and repeating the step (3) until all the substrate units of the substrate are wire-bonded and tested with the O/S test; then proceeding with step (10);
(10) moving the wire-bonded and tested substrate out of the wire bonding station; and
(11) reworking wire-opened or short-circuited substrate units, and tracing and overcoming causes of wire opening or short circuit according to the displayed test results by the displaying module of the testing mechanism.

23. The wire bonding method of claim 22, wherein the testing mechanism includes at least a test socket and a tester electrically connected to the test socket.

24. The wire bonding method of claim 23, wherein the test socket is used to come into contact with the wire-bonded substrate unit, allowing the tester to perform the O/S test for the bonding wires on the substrate unit through the test socket.

25. The wire bonding method of claim 23, wherein the tester at least includes the controlling module, the displaying module and a testing module, the testing module being electrically connected to the test socket so as to perform the O/S test for the substrate unit through the test socket, and transmit test results to the controlling module and the displaying module.

26. The wire bonding method of claim 23, wherein the tester is further electrically connected to a test socket of at least another wire bonding station, so as to simultaneously control test sockets in a plurality of wire bonding stations for performing the O/S test.

27. The wire bonding method of claim 22, wherein the wire bonding station further includes a handling mechanism for moving the substrate into or out of the wire bonding station.

28. The wire bonding method of claim 22, wherein the wire bonding station is a wire bonding machine internally provided with the testing mechanism, and the testing mechanism is disposed at a downstream position relative to the wire bonding mechanism in the wire bonding machine.

29. The wire bonding method of claim 22, wherein the wire bonding station includes a wire bonding machine internally provided with at least a test socket, and a tester externally connected to the wire bonding machine and electrically connected to the test socket, which test socket is disposed at a downstream position relative to the wire bonding mechanism.

30. The wire bonding method of claim 22, wherein in the step (6), upon receiving the control signal from the controlling module of the testing mechanism, the wire bonding mechanism interrupts the wire bonding process after the next adjacent substrate unit is completely wire-bonded.

31. The wire bonding method of claim 22, wherein the substrate units of the substrate are arranged in a matrix type.

32. The wire bonding method of claim 22, wherein the substrate units of the substrate are arranged in a single-array type.

33. A wire bonding system for use in fabrication of a semiconductor package, comprising:
a handling mechanism for moving a substrate into or out of the wire bonding system, the substrate being composed of a plurality of substrate units, with each of the substrate units being mounted with at least a chip;
a wire bonding mechanism for forming bonding wires on the substrate introduced by the handling mechanism, allowing each of the chips to be electrically connected to the corresponding substrate unit by the bonding wires; and
at least a test mechanism for performing an O/S (open/short) test for the bonding wires formed on the substrate introduced by the handling mechanism, the test mechanism being disposed at a downstream position relative to the wire bonding mechanism, wherein, when the test mechanism proceeds with the O/S test for a wire-bonded substrate unit, the wire bonding mechanism simultaneously forms bonding wires on a next adjacent substrate of the substrate, so that test-performing time is included in wire-bonding time for a substrate unit.

34. The wire bonding system of claim 33, wherein the testing mechanism includes at least a test socket and a tester electrically connected to the test socket.

35. The wire bonding system of claim 34, wherein the test socket is used to come into contact with the wire-bonded substrate unit, allowing the tester to perform the O/S test for the bonding wires on the substrate unit through the test socket.

36. The wire bonding system of claim 34, wherein the tester at least includes:
a testing module electrically connected to the test socket, for performing the O/S test through the test socket; and
a controlling module electrically connected to the testing module and the wire bonding mechanism, for receiving a test-failure signal from the testing module in occurrence of wire opening or short circuit, and generating a control signal to the wire bonding mechanism, so as to interrupt a wire bonding process in the wire bonding mechanism.

37. The wire bonding system of claim 36, wherein upon receiving the control signal from the testing mechanism, the wire bonding mechanism interrupts the wire bonding process after the next adjacent substrate unit is completely wire-bonded.

38. The wire bonding system of claim 34, wherein the tester at least includes:
a testing module electrically connected to the test socket, for performing the O/S test through the test socket; and
a displaying module connected to the testing module, for displaying test results from the testing module.

39. The wire bonding system of claim 34, wherein the tester is further electrically connected to a test socket of at least another wire bonding station, so as to simultaneously control test sockets in a plurality of wire bonding stations for performing the O/S test.

40. The wire bonding system of claim 33, wherein the substrate units of the substrate are arranged in a matrix type.

41. The wire bonding system of claim 33, wherein the substrate units of the substrate are arranged in a single-array type.
